(19) United States
(12) Patent Application Publication
(10) Pub. No.: US 2023/0395386 A1
(43) Pub. Date: Dec. 7, 2023

(54) ETCHING PROCESSING APPARATUS AND ETCHING PROCESSING METHOD

(71) Applicants: DAEJEON UNIVERSITY INDUSTRY-UNIVERSITY COOPERATION FOUNDATION, Daejeon (KR); RESEARCH & BUSINESS FOUNDATION SUNGKYUNKWAN UNIVERSITY, Suwon-si (KR)

(72) Inventors: Kyong Nam KIM, Suwon-si (KR); Geun Young YEOM, Seoul (KR); Dong Woo KIM, Seoul (KR); Da In SUNG, Daejeon (KR); Hyun Woo TAK, Suwon-si (KR); Ji Young OH, Jukbyeon-myeon (KR)

(73) Assignees: DAEJEON UNIVERSITY INDUSTRY-UNIVERSITY COOPERATION FOUNDATION, Daejeon (KR); RESEARCH & BUSINESS FOUNDATION SUNGKYUNKWAN UNIVERSITY, Suwon-si (KR)

(21) Appl. No.: 18/234,960

(22) Filed: Aug. 17, 2023

Related U.S. Application Data
(63) Continuation-in-part of application No. PCT/KR2021/016766, filed on Nov. 16, 2021.

(30) Foreign Application Priority Data
Feb. 17, 2021 (KR) 10-2021-0021019

(51) Int. Cl. H01L 21/3065; H01J 37/32

(52) U.S. Cl. CPC H01L 21/3065; H01J 37/32724; H01J 2237/002; H01J 2237/334; H01J 37/32522

(57) ABSTRACT

An etching processing apparatus and an etching processing method using a liquid fluorocarbon or a liquid hydrofluorocarbon precursor are proposed, the etching processing apparatus and etching processing method capable of achieving almost the same effect as cryogenic etching even at a relatively high temperature compared to cryogenic etching. In addition, an etching processing apparatus and an etching processing method capable of solving process problems that may arise due to a liquid precursor and a low temperature may be provided.

### CROSS-REFERENCE TO RELATED APPLICATIONS

This application is a continuation-in-part application which claims to an international application, PCT/KR2021/016766 filed on Nov. 16, 2021 designating the United States, which claims priority to Korean Patent Application No. 10-2021-0021019 filed on Feb. 17, 2021, the disclosure of each of which is incorporated by reference.

### TECHNICAL FIELD

The present disclosure relates to an etching processing apparatus and an etching processing method.

### BACKGROUND ART

In general, a fabrication process of semiconductor devices is accomplished by repeatedly performing a variety of unit processes, such as thin film deposition, etching, cleaning, and photolithography, on a substrate such as a wafer.

Precise control of the etching process is essential to meet the increasing demand for miniaturization and high integration of semiconductor devices. Cryogenic etching is used as an etching method that can obtain high selectivity and high orientation to achieve high performance of semiconductor devices.

Cryogenic etching is performed to etch a substrate while maintaining the substrate at a temperature of −100° C. or lower. In general, in cryogenic etching, plasma is discharged using SF₆ and O₂ gases, and such gases react with a silicon (Si) substrate to form a passivation layer having a chemical formula such as SiOxFy. The passivation layer has etching resistance and serves as a protection layer during the etching process, so that high selectivity and high orientation may be obtained. Accordingly, the cryogenic etching process is used in high aspect ratio (HAR) etching.

However, in the cryogenic etching process, it is difficult to realize equipment and environment for maintaining the substrate at a cryogenic temperature, and the substrate may be damaged by thermal stress. In addition, due to the cold trap principle, surrounding moisture or foreign matter may be adsorbed to the substrate in the cryogenic environment, thereby contaminating the substrate or causing a defect in the substrate.

### DISCLOSURE

### Technical Problem

Accordingly, the present disclosure is intended to provide an etching processing apparatus and an etching processing method able to obtain the same effects (i.e., high selectivity, high orientation, and a high aspect ratio) at a temperature higher than in conventional cryogenic etching.

In addition, the present disclosure is intended to provide an etching processing apparatus and an etching processing method able to prevent contamination that would otherwise be caused by low-temperature adsorption resulting from a low-temperature environment.

The objectives of the present disclosure are not limited to the aforementioned description, and other objectives of the present disclosure not explicitly described will be clearly understood from the description provided hereinafter by those skilled in the art to which the present disclosure pertains.

### Technical Solution

According to an embodiment of the present disclosure, provide is an etching processing apparatus including: a chamber providing a substrate processing space; a substrate support unit supporting a substrate; a cooling unit configured to cool the substrate support unit; a gas supply unit configured to evaporate an etching precursor existing as a liquid at room temperature and supply a gas of the evaporated etching precursor into the chamber; a plasma generation unit configured to excite the gas supplied into the chamber; and a chamber heating unit configured to heat a wall of the chamber.

The etching precursor may have a boiling point of 0° C. or higher in an atmospheric pressure and is one material of fluorocarbon-based materials that are compounds of carbon and fluorine.

The etching precursor may have a boiling point of 0° C. or higher in an atmospheric pressure and is one material of hydrofluorocarbon based materials that are compounds of carbon, fluorine, and hydrogen.

The cooling unit may cool the support unit to a temperature of −50° C. to 50° C.

The chamber heating unit may include a light source configured to heat the wall of the chamber by irradiating the chamber with light.

The chamber heating unit may prevent the precursor from being adsorbed to an interior of the chamber.

The chamber heating unit may heat the wall of the chamber to a temperature higher than the boiling point of the etching precursor.

The chamber heating unit may heat the wall of the chamber to a temperature of 30° C. to 150° C.

According to an embodiment of the present disclosure, provide is an etching processing method including: a preparation step including a step of inputting an object to be etched into a chamber and preparing an etching precursor to be supplied into the chamber; a cooling step of cooling the object to be etched; a chamber wall heating step of heating a wall of the chamber; a precursor supply step of supplying the etching precursor into the chamber; a plasma generation step of generating plasma inside the chamber; and an etching step of etching the object to be etched using the etching precursor ionized by the plasma. The etching precursor may have a boiling point of 0° C. or higher in an atmospheric pressure and is one of fluorocarbon-based materials that are compounds of carbon and fluorine and hydrofluorocarbon based materials that are compounds of carbon, fluorine, and hydrogen.

In the cooling step, the object to be etched may be cooled to a temperature of −50° C. to 50° C.

In the chamber wall heating step, the wall of the chamber may be heated to a temperature higher than the boiling point of the etching precursor.

In the chamber wall heating step, the wall of the chamber may be heated to a temperature of 30° C. to 150° C.

In the chamber wall heating step, the precursor may be prevented from being adsorbed to an interior of the chamber.

The chamber wall heating step may be continuously performed at least while the precursor supply step, the plasma generation step, and the etching step are being performed.

### Advantageous Effects

According to embodiments of the present disclosure, the characteristics of conventional cryogenic etching may be realized using a liquid precursor at a temperature higher than in conventional cryogenic etching, and thus processing equipment and environment may be easily realized. In addition, a substrate may be prevented from being damaged by thermal stress.

In addition, according to embodiments of the present disclosure, the provision of the chamber wall heating unit configured to control the temperature of the wall of the chamber by heating the wall of the chamber may prevent the interior of the chamber except for the substrate from being contaminated.

The effects of the present disclosure are not limited to the aforementioned description, and other effects of the present disclosure not explicitly described will be clearly understood from the description provided hereinafter and the accompanying drawings by those skilled in the technical field to which the present disclosure pertains.

### DESCRIPTION OF DRAWINGS

FIG. 1 is a diagram schematically illustrating an etching processing apparatus according to embodiments of the present disclosure;

FIG. 2 is a flowchart illustrating an etching processing method according to embodiments of the present disclosure;

FIG. 3 is a cross-sectional diagram illustrating an example of a pattern having a high aspect ratio obtainable by cryogenic etching;

FIG. 4 is a graph comparing the etch rate of conventional cryogenic etching with the etch rate of embodiments of the present disclosure; and

FIG. 5 is a graph is a graph comparing the etch rate of atomic layered etching using a liquid fluorocarbon precursor and the etch rate of sputtering according to the temperature of the substrate.

### BEST MODE

Hereinafter, embodiments of the present disclosure will be described in detail with reference to the accompanying drawings so that those skilled in the art to which the present disclosure pertains may easily put the present disclosure into practice. However, the present disclosure may be variously modified or altered in forms but is not limited to following embodiments.

In the following description of the present disclosure, a detailed description of related known functions or elements will be omitted in the situation in which the subject matter of the present disclosure may be rendered unclear thereby. Portions having similar functions or actions will be designated by the same reference numerals throughout the drawings.

Some of the terms used herein are defined in consideration of functions thereof in the present disclosure, and may be varied according to the intention of a user or an operator, customs, and the like. Therefore, these terms should be defined on the basis of the contents of the entire specification.

It will be understood that terms “comprise”, “include”, “have”, and any variations thereof used herein are intended to cover non-exclusive inclusions unless explicitly described to the contrary. In addition, it will be understood that when an element is referred to as being “connected (or coupled)” to another element, not only can it be “directly connected (or coupled)” to the other element, but it can also be “indirectly connected (or coupled)” to the other element via an intervening element.

In addition, sizes or shapes of constituent elements and thicknesses of lines in the drawings may be exaggerated for convenience of understanding.

Embodiments of the present disclosure will be described with reference to schematic drawings of ideal embodiments of the present disclosure. Accordingly, changes from the shapes of figures, for example, changes in manufacturing methods and/or tolerances, are fully expectable. Accordingly, embodiments of the present invention are not described as being limited to particular shapes of areas illustrated as the figures, but to include variations in the shapes. Elements described in the drawings are merely schematic, and the shapes thereof are neither intended to render accurate shapes of the elements nor intended to limit the scope of the present invention.

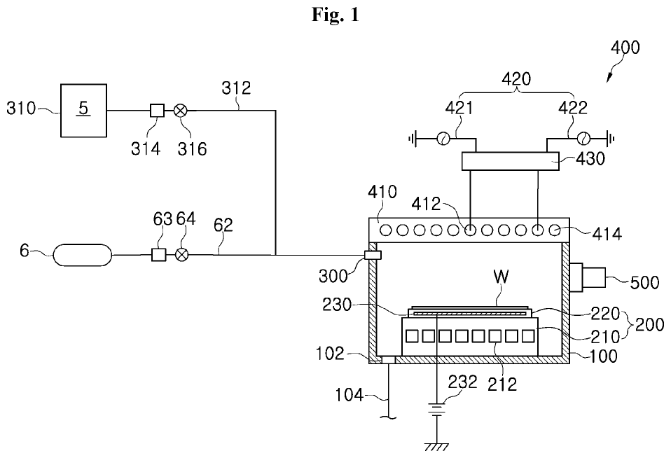

As illustrated in FIG. 1, an etching processing apparatus according to embodiments of the present disclosure may include a chamber 100, a substrate support unit 200, a gas supply unit 300, a plasma generator unit 400, and a chamber heating unit 500. The etching processing apparatus according to embodiments of the present disclosure may be an inductively-coupled plasma device.

The chamber 100 provides an internal processing space in which a substrate W is to be etched. Etching processing may be performed in a vacuum atmosphere. The chamber 100 may be configured to be sealed hermetically, and may have a door (not shown) in a sidewall. A substrate W may be input into the processing space in the chamber 100. The substrate W may be input into the processing space in the chamber 100 through the door and be removed from the processing space in the chamber 100 through the door. The door may be configured to be opened and closed by a separate drive unit (not shown). The chamber 100 may be grounded, and a ventilation hole 102 may be formed in the bottom of the chamber 100. Although not illustrated in detail, the ventilation hole 102 may be connected to a ventilation line 104 and a ventilation pump (not shown). Reaction byproducts generated during the processing and gases staying within the inner space of the chamber 100 may be discharged through the ventilation hole 102. Due to the discharging, the interior of the chamber 100 may be decompressed to a predetermined pressure.

The substrate support unit 200 configured to support the substrate W may be provided within the chamber 100. The substrate support unit 200 may include an electrostatic chuck 220 configured to attract and hold the substrate W and a base plate 210 supporting the electrostatic chuck 220. The electrostatic chuck 220 may be implemented using a dielectric material plate of, for example, alumina. A chuck electrode 230 for generating electrostatic force may be provided inside the electrostatic chuck 220. When a voltage is applied to the chuck electrode 230 from a power source 232, electrostatic force may by generated so that the substrate W may be attracted and held by the electrostatic chuck 220.

The base plate 210 is located below the electrostatic chuck 220, and may be made of a metal material such as aluminum (Al). The base plate 210 may include a cooling unit 212 therein. The cooling unit 212 may include a refrigerant flow path through which refrigerant (or cooling fluid) flows so as to serve as a cooling means to cool the electrostatic chuck 220. The refrigerant flow path may be formed inside the base plate 210 a circulation path allowing refrigerant to circulate therethrough. The electrostatic chuck 220 may be cooled by the circulation of refrigerant, thereby cooling the substrate W supported on the electrostatic chuck 220 to an intended temperature.

Although not shown, a heat transfer gas supply path is formed in the base plate 210 and the electrostatic chuck 220, and heat transfer gas is supplied to the rear surface of the substrate W. Thus, heat transfer may be obtained between the cooling unit 212 and the substrate W by means of heat transfer gas so as to cool the substrate W.

According to embodiments of the present disclosure, the cooling unit 212 may cool the electrostatic chuck 220 so that the temperature of the substrate W is maintained at a temperature in the range of −50° C. to 50° C.

The gas supply unit 300 may include a supply nozzle 300 connected to a gas supply unit 310 as a component to supply processing gas for the etching processing. The supply nozzle 300 may be provided on a sidewall of the chamber 100. Although the gas supply unit is illustrated as being implemented as the supply nozzle in FIG. 1, the present disclosure is not limited thereto. For example, a shower head including a plurality of injection holes may be provided on the top of the chamber 100 to face the substrate such that gas may be injected into the chamber 100 from the shower head.

The gas supply unit 310 may include an etching precursor 5 as a component to supply gas to the gas supply unit 300. For example, the gas supply unit 310 may be a canister. The etching precursor 5 according to the present disclosure may exist as a liquid at room temperature. That is, the etching precursor 5 may be a material, the boiling point of which is 0° C. or higher in the atmospheric pressure. The etching precursor 5 may be a material that can react with and etch a layer of the substrate W to be etched. For example, the layer to be etched may be a silicon (Si) oxide layer. Here, the layer to be etched may be etched in a specific pattern comprised of, for example, holes or trenches. In this regard, a mask layer may be patterned on the top of the layer to be etched. The mask layer may be a silicon nitride (Si₃N₄) layer or an amorphous carbon layer (ACL). In order to obtain an etch selectivity, the etch rate of the etching precursor 5 may be higher for the layer to be etched and low for the mask layer. The etching precursor 5 according to embodiments of the present disclosure may be one of fluorocarbon (CF) based materials that are compounds of carbon and fluorine atoms. Alternatively, the etching precursor 5 according to embodiments of the present disclosure may be one of hydrofluorocarbon (HFC) based materials that are compounds of carbon, fluorine, and hydrogen atoms. The etching precursor 5 according to embodiments of the present disclosure exists as a liquid at room temperature and thus has high absorptivity to the substrate.

Specifically, the etching precursor 5 according to embodiments of the present disclosure may be one among C₆F₆, C₅F₁₀, C₅F₁₂, C₆F₁₀, C₆F₁₂, C₆F₁₄, C₇F₁₄, C₇F₁₆, and C₅F₁₆. Alternatively, the etching precursor 5 according to embodiments of the present disclosure may be one among C₃H₂F₆, C₄H₂FE, C₄H₂F₅, C₄H₄F₆, C₅HF₉, C₅H₂F₈, C₅H₇, C₅H₃F₇, C₆HF₁₃, C₆H₂F₁₂, C₆H₅F₉, C₆H₇F₇, C₆H₈FE, C₆H₃F₉, C₆H₄F₈, and C₆H₅F₇.

When the processing is performed, the etching precursor 5 may be maintained as a liquid. The gas supply unit 310 may be provided with a separate heating system to evaporate the liquid etching precursor 5 and supply the gaseous etching precursor 5 to the chamber 100. The etching precursor 5 evaporated from the liquid state by the heating system may be transferred to the gas supply unit 300 through a gas flow path 312. A mass flow controller (MFC) 314 and a valve 316 for regulating the flow rate of gas may be provided on the gas flow path 312. A storage container may be provided with a temperature maintaining part (not shown) by which the etching precursor 5 may be maintained at a predetermined temperature. The temperature maintaining part may be a heater or a cooler.

The plasma generator unit 400 is a component to generate plasma in the processing space in the chamber 100. The plasma generator unit 400 may excite the gas (i.e., the etching precursor evaporated from the liquid state) supplied into the chamber 100 by applying electric power to the gas.

Plasma may be generated by a variety of methods. For example, plasma may be an inductively coupled plasma (ICP), a capacitively coupled plasma (CCP), or a remote plasma. Referring to an ICP apparatus illustrated in FIG. 1 as an example, the plasma generator unit 400 may include a coil-shaped plasma source 410 disposed on the top of the chamber 100 and one or more radio frequency (RF) power sources 420 configured to apply electric power to the plasma source 410. The plasma source 410 and the RF power sources 420 may be electrically connected, and a matching unit 430 may be provided between the plasma source 410 and the RF power sources 420.

The plasma source 410 may induce a time-varying magnetic field to the chamber by receiving RF power from the RF power sources 420, so that a process gas supplied to the chamber 100 may be excited into a plasma. That is, the plasma source 410 may induce an electromagnetic field into the chamber 100 by receiving RF power. Although not shown, the plasma generator unit 400 may further include an electromagnetic field controller configured to control the electromagnetic field induced by the plasma source 410.

For example, the plasma source 410 may include a flat coil comprising one or more windings. That is, the plasma source 410 may be implemented as a plurality of coils to which RF power is applied from different power sources.

For example, as illustrated in FIG. 1, the plasma source 410 may include a first coil 412 located in the inner portion of the top of the chamber 100 and a second coil 414 located in the outer portion of the top of the chamber 100 to surround the first coil 412. The RF power sources 420 may include a first RF power source 421 connected to the first coil 412 and a second RF power source 422 connected to the second coil 414. The first RF power source 421 may apply FR power to the first coil 412, while the second RF power source 422 may apply FR power to the second coil 414.

The RF power sources 420 may provide RF power for generating and maintaining a plasma. The first RF power source 421 and the second RF power source 422 may output different frequencies of RF power, respectively. The matching unit 430 is a device to match impedances and loads, i.e., impedances, on the RF power sources 421 and 422 sides. The matching unit 430 may include a plurality of matching circuits to correspond to the first RF power source 421 and the second RF power source 422, respectively. In addition to the first RF power source 421 and the second RF power source 422, a third RF power source configured to generate a third frequency of RF power may be provided. Alternatively, a bias power source may be connected to a base plate 220, and a DC power source may be used as the bias power source. Alternatively, both the first and second coils 412 and 414 may receive electric power from a single RF power source.

The structure of the plasma source 410 is not limited to the above-described embodiments. For example, the plasma source 410 may be implemented as a single coil including at least one winding.

At least one processing gas 6 different from the etching precursor 5 may be supplied to the gas supply unit 300. The processing gas may be supplied to control the etch rate or the etch selectivity. For example, the processing gas 6 may be oxygen (02) or hydrogen (H₂). The processing gas 6 may be connected to the gas supply unit 300 through a gas flow path 62. An MFC 63 and a valve 64 configured to control the flow rate of a gas may be disposed on the gas flow path 62.

The etching processing apparatus according to embodiments of the present disclosure is a low-temperature etching processing apparatus using plasma, and uses a liquid precursor having a high boiling point. The liquid precursor may be used as an etching gas to react with a Si wafer to form a passivation film on a sidewall of a layer to be etched (e.g., a trench). Thus, a high aspect ratio, high selectivity, and high orientation that can be obtained by cryogenic etching may be obtained at temperatures relatively high compared to a cryogenic temperature.

The chamber heating unit 500 is a component to heat the wall of the chamber 100. The chamber heating unit 500 may include a heat source to heat the wall of the chamber 100. The chamber heating unit 500 may use electromagnetic waves to heat the wall of the chamber 100. For example, a light source, such as an infrared (IR) lamp, an ultraviolet (UV) lamp, a halogen lamp, a light-emitting diode (LED), an incandescent lamp, or a fluorescent lamp, may be used. it is possible to prevent the interior of the chamber from being contaminated by the precursor. The chamber heating unit 500 may be provided to be in contact with the outer wall of the chamber 100 to directly heat the wall of the chamber 100. Alternatively, the chamber heating unit 500 may be supported on a separate support member spaced apart a predetermined distance from the chamber 100 and be configured to transfer radiant heat to the outer wall of the chamber 100.

Since the etching precursor 5 according to embodiments of the present disclosure exists as a liquid at room temperature, the etching precursor 5 may be adsorbed not only to the substrate W but also to the components inside the chamber 100, such as the inner wall of the chamber 100, the electrostatic chuck 220, the gas flow path 312, and the supply nozzle 300. The liquid precursor adsorbed to the components inside the chamber 100 may be a contaminant of the chamber and/or be polymerized by plasma. The contamination of the chamber may influence the reliability of the process. In addition, when the precursor is polymerized by being adsorbed to the electrostatic chuck 220 made of a dielectric, it may be difficult to stably supply electric power to the electrostatic chuck 220 due to the polymerized portion of the precursor. In addition, the DC voltage induced to the substrate may vary depending on the thickness of the polymerized portion and the degree of contamination, thereby changing the distribution of ion energy. With changes in the impedance of the chamber, the uncertainty of the process may increase. That is, the reliability of the process may be significantly influenced.

Thus, in order to prevent the liquid precursor from being adsorbed to an area other than the substrate, the chamber heating unit 500 may be provided to heat the wall of the chamber 100. Here, the wall of the chamber 100 may be heated to a temperature higher than the boiling point of the liquid precursor. For example, the wall of the chamber 100 may be heated to a temperature in the range of 30° C. to 150° C. Here, the substrate support unit 200 may be configured to be liftable in order to minimize the influence of the chamber heating unit 500 on the substrate W.

Although a single etching precursor 5 is illustrated in FIG. 1, a plurality of etching precursors may be provided. In addition, a configuration allowing an inert gas such as argon (Ar) or helium (He) to be independently supplied to the gas supply unit 300 may be provided.

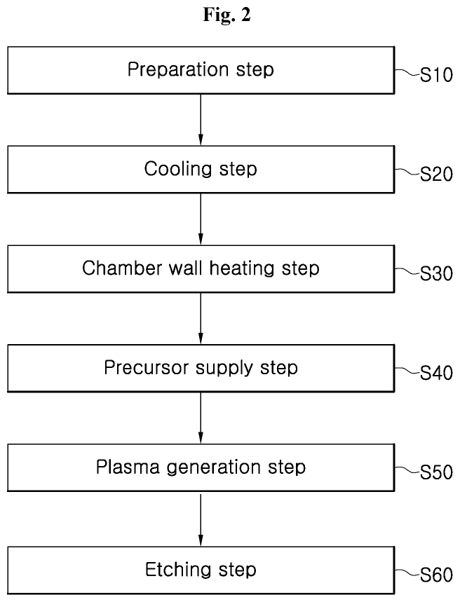

FIG. 2 is a flowchart illustrating a dry etching method as an etching processing method according to embodiments of the present disclosure. Referring to FIGS. 1 and 2, the dry etching method according to embodiments of the present disclosure may include a preparation step S10, a cooling step S20, a chamber wall heating step S30, a precursor supply step S40, a plasma generation step 550, and an etching step S60.

The preparation step S10 may include a step of inputting an object to be etched into the chamber and preparing the etching precursor 5 to be supplied into the chamber.

For example, the object to be etched may be the substrate W subject to the processing. The preparation step S10 may include a step of seating the substrate W input into the chamber on the substrate support unit 200. When the substrate W is seated, a voltage may be applied to the chuck electrode 230 by the power source 232, so that the substrate W may be electrostatically attracted to the electrostatic chuck 220.

The etching precursor 5 used in an etching processing method according to embodiments of the present disclosure may be a fluorocarbon (CF) or hydrofluorocarbon (HFC) based precursor existing as a liquid at room temperature. Thus, the preparation step S10 may include a step of evaporating the etching precursor 5 existing as a liquid at room temperature by heating the etching precursor 5 using the heating system. Alternatively, the etching precursor 5 existing as a liquid at room temperature may be evaporated by a bubbling method.

In addition, the preparation step S10 may further include a vacuuming step of controlling the pressure within the chamber 100 at a predetermined vacuum pressure.

The cooling step S20 may be a step of cooling the substrate W, i.e., an object to be etched, by cooling the electrostatic chuck 220. Due to the cooling step S20, the temperature of the substrate W may be cooled to a temperature in the range of −50° C. to 50° C.

The chamber wall heating step S30 may be a step of heating the wall of the chamber 100, thereby preventing the interior of the chamber from being contaminated by the etching precursor 5 existing as a liquid at room temperature. The chamber wall heating step S30 may heat the wall of the chamber 100 by irradiating the wall of the chamber 100 with light using a light source, such as an IR lamp, a UV lamp, a halogen lamp, an LED, an incandescent lamp, or a fluorescent lamp. The wall of the chamber 100 may be heated by another heat source other than the light source. Due to the chamber wall heating step S30, the wall of the chamber 100 may be heated to a temperature higher than the boiling point of the liquid precursor. For example, the wall of the chamber 100 may be heated to a temperature in the range of 30° C. to 150° C.

The cooling step S20 and the chamber wall heating step S30 may be performed throughout the processing. That is, the cooling step S20 and the chamber wall heating step S30 may be maintained until all of the etching processing steps are completed.

The precursor supply step S40 may be a step of supplying an etching gas into a vacuum chamber. The etching gas may be the etching precursor 5 delivered after being heated by the heating system. Alternatively, at least one processing gas 6 and/or an inert gas may be supplied at predetermined ratios together with the etching precursor 5. For example, at least one of oxygen (O₂) and argon (Ar) may be supplied together with the etching precursor 5. The etching gas may be discharged into the chamber 100 by means of the gas supply unit 300.

Afterwards, the plasma generation step 550 that generates plasma using the etching gas may be performed. In this regard, RF power may be applied by the RF power sources 420 connected to the plasma source 410. The RF power sources 420 may include two or more RF power sources 421 and 422. In addition, a bias voltage may be applied to the substrate through the base plate 210.

The etching step S60 may be a step in which the etching precursor 5 is ionized by plasma and input toward the substrate W so that a layer to be etched is etched, and may be a step of etching the layer to be etched in a predetermined pattern. In this regard, a patterned mask layer may be provided on the layer to be etched.

When the etching step S60 is completed, a step of finishing the process and removing the substrate may be performed. The removing of the substrate may be a step of holding and removing the substrate W by means of a substrate transport robot that has entered the chamber from a transport module disposed to be able to communicate with the chamber 100.

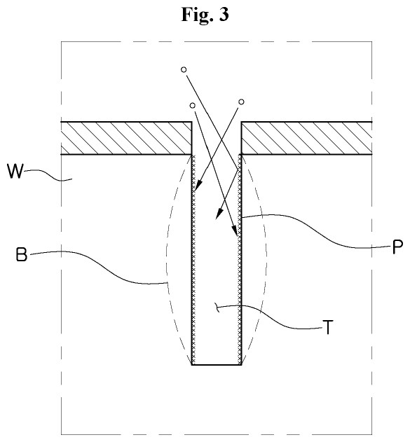

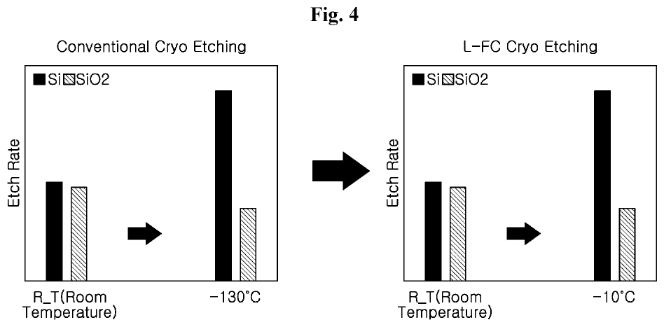

Hereinafter, a result obtained by performing the Si oxide film etching process using the liquid etching precursor 5 according to the present disclosure will be described in relation to a specific embodiment. FIG. 3 is a cross-sectional view illustrating a pattern having a high aspect ratio generally obtainable by cryogenic etching, and FIG. 4 is a graph comparing the etch rate of conventional cryogenic etching with the etch rate of embodiments of the present disclosure.

According to conventional cryogenic etching, a structure such as a trench T having a high aspect ratio may be formed by performing plasma etching at a cryogenic temperature (e.g., −100° C. or lower). When the trench T having a high aspect ratio is formed, an undesired profile may occur in the etching. For example, as indicated with dotted lines in FIG. 3, when the aspect ratio of the trench T is higher, the trench T may more likely to have a bowing shape B. In order to prevent this, a passivation layer P for protecting the etched sidewall may be formed by supplying a passivation gas separately from the etching gas. However, when a fluorine-rich gas, such as CF₄ or SF₆, is supplied as a plasma etching gas, the etching gas may also act as a passivation gas at a low temperature of 100° C. or lower. That is, as illustrated in FIG. 3, at least one of CF₄ and SFr may act as an etching gas while acting as a passivation gas on the inner wall of the trench T to form the passivation layer P, thereby preventing an undesired profile in the structure such as a trench having an intended high aspect ratio.

However, although CF₄ and SF₆ essentially require a cryogenic environment due to low boiling points, it is significantly difficult to realize at least one of equipment and environment for maintaining the substrate at a cryogenic temperature. Even in the case that at least one of the equipment and the environment are realized, thermal stress due to the cryogenic temperature may cause damage to the substrate.

In contrast, the etching precursor 5 according to embodiments of the present disclosure contains fluorine and has a boiling temperature of 0° C. or higher. Thus, the etching precursor 5 may perform low-temperature plasma etching at a temperature higher than the cryogenic environment. Accordingly, it is relatively easy to realize at least one of the processing environment and the equipment and to prevent thermal stress. In addition, with reference to FIG. 4, it can be seen that etching using the liquid fluorocarbon precursor may have effects significantly similar to those of cryogenic etching. That is, similar effects may be realized by the etching using the liquid fluorocarbon precursor at a higher temperature than cryogenic etching.

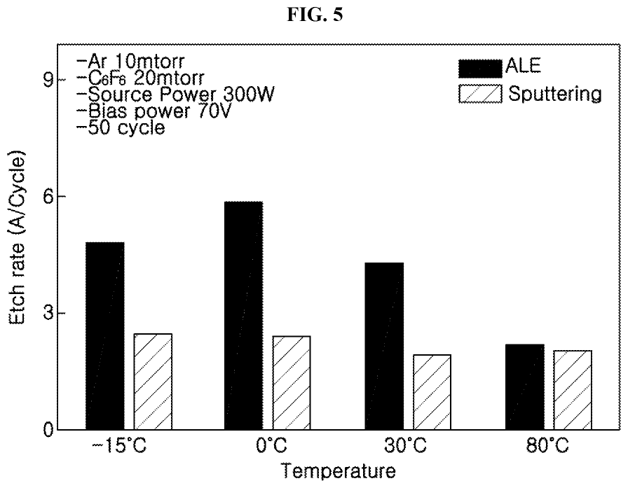

FIG. 5 is a graph is a graph comparing the etch rate of atomic layered etching (ALE) using a liquid fluorocarbon precursor (e.g., C₆F₆) and the etch rate of sputtering according to the temperature of the substrate W. ALE includes a circulation cycle comprised of adsorption, purging, desorption, and purging operations. An object to be etched may be etched by the adsorption and the desorption among the above operations. When the precursor supplied to the object to be etched is adsorbed to the surface of the object to be etched and then desorbed together with a surface layer, the object to be etched may be etched.

Referring to FIG. 5, it can be seen that the difference in the etch rate between ALE and sputtering decreases with increases in the temperature of the object to be etched (e.g., a substrate). In particular, it can be seen that at a temperature of 0° C. or higher, the etch rate of ALE significantly decreases with increases in the temperature of the object to be etched. This phenomenon may be interpreted as a phenomenon caused by a decrease in the amount of the liquid fluorocarbon precursor adsorbed to the surface of the object to be etched of the liquid fluorocarbon precursor supplied to the object to be etched in response to an increase in the temperature of the object to be etched. Accordingly, it can be seen that the processing temperature may be maintained at 30° C. or lower in order to form the adsorption layer on the surface of the object to be etched by supplying the liquid fluorocarbon precursor to the object to be etched.

When these are applied to embodiments of the present disclosure, the adsorption layer formed on the surface of the object to be etched may serve as a passivation layer P for the sidewall of a layer to be etched, thereby realizing an etching process having a high aspect ratio, high selectivity, and high orientation. That is, it is estimated that effects similar to those of cryogenic etching may be obtained by performing an etching process using the liquid fluorocarbon precursor at a temperature of 30° C. or lower.

In addition, the etching precursor 5 existing as a liquid at room temperature may be adsorbed not only to the substrate W but also to the components inside the chamber 100, such as the gas flow path 312, the inner wall of the chamber 100, and the gas supply nozzle 300. The liquid precursor adsorbed to the components inside the chamber 100 may be a contaminant of the chamber and/or be polymerized by plasma. The contamination of the chamber may influence the reliability of the process. In addition, when the precursor is polymerized by being adsorbed to the electrostatic chuck 220 made of a dielectric, it may be difficult to stably supply electric power to the electrostatic chuck 220 due to the polymerized portion of the precursor. Thus, with changes in the DC voltage induced to the substrate, the distribution of ion energy may be changed. With changes in the impedance of the chamber, the uncertainty of the process may increase.

The above-described problems may be overcome by removing the reasons of the above-described problems by the etching processing apparatus provided with the chamber wall heating unit for heating the chamber wall and the etching processing method including the chamber wall heating step.

As set forth above, the cryogenic etching characteristics may also be maintained by using the etching precursor existing as a liquid at room temperature and containing fluorine. In addition, after the etching process, a discharge gas may be recovered as a liquid in a discharge area, and thus the discharge of greenhouse gases may be minimized.

It will be apparent to those skilled in the art to which the present disclosure pertains that the present disclosure may be variously modified and altered in forms without departing from the spirit of the present disclosure or changing essential features thereof. Accordingly, the foregoing embodiments shall be interpreted as being illustrative, while not being limitative, in all aspects.

It should be understood that the scope of the present disclosure shall be defined by the appended Claims rather than by the foregoing embodiments, and that all of modifications and alterations derived from the definition of the Claims and their equivalents fall within the scope of the present disclosure.

1. An etching processing apparatus comprising:
a chamber providing a substrate processing space;
a substrate support unit supporting a substrate;
a cooling unit configured to cool the substrate support unit;
a gas supply unit configured to evaporate an etching precursor existing as a liquid at room temperature and supply a gas of the evaporated etching precursor into the chamber;
a plasma generation unit configured to excite the gas supplied into the chamber; and
a chamber heating unit configured to heat a wall of the chamber.

2. The etching processing apparatus of claim 1, wherein the etching precursor has a boiling point of 0° C. or higher in an atmospheric pressure and is one material of fluorocarbon-based materials that are compounds of carbon and fluorine.

3. The etching processing apparatus of claim 1, wherein the etching precursor has a boiling point of 0° C. or higher in an atmospheric pressure and is one material of hydrofluorocarbon based materials that are compounds of carbon, fluorine, and hydrogen.

4. The etching processing apparatus of claim 1, wherein the cooling unit cools the support unit to a temperature of −50° C. to 50° C.

5. The etching processing apparatus of claim 1, wherein the chamber heating unit comprises a light source configured to heat the wall of the chamber by irradiating the chamber with light.

6. The etching processing apparatus of claim 5, wherein the chamber heating unit prevents the precursor from being adsorbed to an interior of the chamber.

7. The etching processing apparatus of claim 6, wherein the chamber heating unit heats the wall of the chamber to a temperature higher than the boiling point of the etching precursor.

8. The etching processing apparatus of claim 7, wherein the chamber heating unit heats the wall of the chamber to a temperature of 30° C. to 150° C.

9. An etching processing method comprising:
a preparation step comprising a step of inputting an object to be etched into a chamber and preparing an etching precursor to be supplied into the chamber;
a cooling step of cooling the object to be etched;
a chamber wall heating step of heating a wall of the chamber;
a precursor supply step of supplying the etching precursor into the chamber;
a plasma generation step of generating plasma inside the chamber; and
an etching step of etching the object to be etched using the etching precursor ionized by the plasma,
wherein the etching precursor has a boiling point of 0° C. or higher in an atmospheric pressure and is one of fluorocarbon-based materials that are compounds of carbon and fluorine and hydrofluorocarbon based materials that are compounds of carbon, fluorine, and hydrogen.

10. The etching processing method of claim 9, wherein in the cooling step, the object to be etched is cooled to a temperature of −50° C. to 50° C.

11. The etching processing method of claim 9, wherein in the chamber wall heating step, the wall of the chamber is heated to a temperature higher than the boiling point of the etching precursor.

12. The etching processing method of claim 11, wherein in the chamber wall heating step, the wall of the chamber is heated to a temperature of 30° C. to 150° C.

13. The etching processing method of claim 12, wherein in the chamber wall heating step, the precursor is prevented from being adsorbed to an interior of the chamber.

14. The etching processing method of claim 9, wherein the chamber wall heating step is continuously performed at least while the precursor supply step, the plasma generation step, and the etching step are being performed.
